(19) United States
(12) Patent Application Publication
(10) Pub. No.: US 2025/0113620 A1
(43) Pub. Date: Apr. 3, 2025

(54) Distributed Gate Drive for DrMOS

(71) Applicant: Alpha and Omega Semiconductor International LP, Toronto (CA)

(72) Inventors: Shekar Mallikarjunaswamy, San Jose, CA (US); Shanghui Tu, San Diego, CA (US)

(21) Appl. No.: 18/374,297

(22) Filed: Sep. 28, 2023

(51) Int. Cl. H01L 27/02; H01L 23/498; H01L 25/065; H01L 27/06; H01L 27/092; H01L 29/08

(52) U.S. Cl. CPC H10D 89/10; H01L 23/49822; H01L 23/49838; H01L 25/0655; H10D 62/154; H10D 62/158; H10D 84/853; H10D 88/00

(57) ABSTRACT

A transistor device comprising a semiconductor substrate composition a first gate electrode material disposed over a portion of a surface of the substrate composition wherein the first gate electrode material includes a first gate electrode contact region near at least one edge of the substrate composition. A gate insulating material is located over the first gate electrode material including two or more first gate vias through the gate insulating material in the first gate electrode contact region wherein the two or more first gate vias expose the first gate electrode material. A transistor device package includes a gate controller integrated circuit including a first transistor gate driver output node. A first gate conductive redistribution material connects the first gate electrode material of the first transistor device to the output node of the gate controller integrated circuit through the two or more first gate vias.

### FIELD OF THE DISCLOSURE

Aspects of the present disclosure relate to Driver-MOSFET (DrMOS) devices specifically aspects of the present disclosure relate to wafer level packaging and drivers in DrMOS devices.

### BACKGROUND OF THE DISCLOSURE

In conventional DrMOS devices transistor drivers are packaged with transistor devices in a multi-chip package. The current popular multi-chip packages include Quad Flat-no lead (QFN) and flip chip, which use bond wires to connect chips within the package to a lead frame. Flip chip packages include the use of a clip to connect the backside of the chip to the lead frame.

FIG. 1A and FIG. 1B schematically depict a prior art flip chip design. As shown the flip chip package includes a gate controller integrated circuit 101, a high side metal oxide semiconductor field effect transistor (MOSFET) 103, low side MOSFET 102, lead frame 107, and backside clip 110. The gate of the low side MOSFET 102 includes a large gate contact pad 104 that is required for the gate contact pad to have sufficient area for connection to the transistor driver 101. A large soldered joint 111 makes the connection between the gate contact pad 104 and the lead frame 107. Metal bond wires 106 connect the lead frame with the transistor driver allowing the transistor to send signals to the gate contact pad 104 of the low side MOSFET 102 through the large soldered joint 111. The high side MOSFET 103 also includes a large gate contact pad 105, a high side gate bond wire 108 connects the gate contact pad 105 to the high side gate control output node of the transistor driver 101. The large gate contact pads take up significant amounts of space in the low side MOSFET 102 and the High side MOSFET 103, the space underneath the gate contact pads is wasted because there is no active area under the gate pads. The transistor driver 101 also includes pads for other control inputs which are connected to the lead frame 107 by bond wires 109. As seen in FIG. 1B a backside clip 110 connects the source of the high side MOSFET 103 to the drain low side MOSFET 102 to the VSWH pin-out of the lead frame 107. Bond wires require space within the device package because each wire must be separated with a gap large enough to ensure there is no arcing between leads and the pad must be large enough on each device that a bond can be made. Additionally, the bond wires have a large inductance compared to thin metal leads. The lead frame and clip also present a size disadvantage as a metal clip must be provided with enough strength to hold contact with the backside of the chip. Finally, the large single bond pads create an issue because the gate impedance is non-uniform which causes non-uniform switching of the transistor device.

It is within this context that aspects of the present disclosure arise.

### BRIEF DESCRIPTION OF THE DRAWINGS

The teachings of the present disclosure can be readily understood by considering the following detailed description in conjunction with the accompanying drawings, in which:

FIG. 1A is a top-down schematic diagram of a prior art flip chip design.

FIG. 1B is a side view of the prior art flip chip design.

FIG. 2 is a top-down view of the redistribution layer (RDL) of a transistor device according to aspects of the present disclosure.

FIG. 3 is a top-down view of the RDL of a DRMOS device having a distributed gate drive with a single gate bus for the gates of each MOSFET according to aspects of the present disclosure.

FIG. 4 is a top-down view of the RDL of a DRMOS device having a distributed gate drive with multiple proportionally distributed gate busses for the gates of each MOSFET according to aspects of the present disclosure.

FIG. 5 is a top-down view of the RDL of a DRMOS device having a distributed gate drive with multiple equally distributed gate busses for the gate electrode contact regions located on two top sides of each FET device according to aspects of the present disclosure.

FIG. 6 is a top-down view of the RDL of a DRMOS device having a distributed gate drive with multiple proportionally distributed gate busses for the gate electrode contact regions located on two top sides of each FET device including a sense FET according to aspects of the present disclosure.

FIG. 7 is a top-down view of the RDL of a DRMOS device having a FET device integrated with the gate control and a distributed gate drive with multiple proportionally distributed gate busses for the gate electrode contact regions located on a top edge of the separate FET device according to aspects of the present disclosure.

FIG. 8 is a top-down view of the RDL of a DRMOS device having integrated trench capacitors in the semiconductor wafer according to aspects of the present disclosure.

FIG. 9 is a top-down view of the RDL of a DRMOS device illustrating the distributed gate drivers according to aspects of the present disclosure.

FIG. 10 is a top-down view of the RDL of a DRMOS device including split FET devices according to aspects of the present disclosure.

FIG. 11A is a cutaway side view of a shielded gate trench (SGT) MOSFET device in an implementation of the DRMOS according to aspects of the present disclosure taken along line A-A of FIG. 10.

FIG. 11B is a cutaway side view of a shielded gate trench (SGT) MOSFET device in an implementation of the DRMOS according to aspects of the present disclosure taken along line B-B of FIG. 10.

FIG. 12A is a cutaway side view of a planar gate MOSFET device in an implementation of the DRMOS according to aspects of the present disclosure taken along line A-A of FIG. 10.

FIG. 12B is a cutaway side view of a planar gate MOSFET device in an implementation of the DRMOS according to aspects of the present disclosure taken along line B-B of FIG. 10.

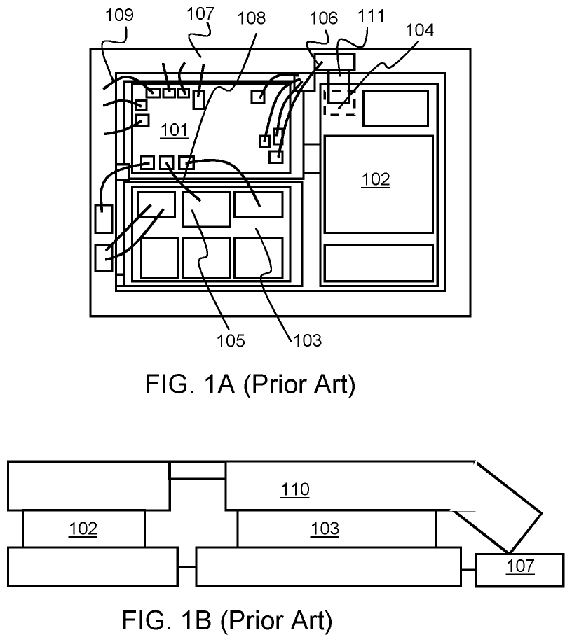

### DESCRIPTION OF THE SPECIFIC EMBODIMENTS

Although the following detailed description contains many specific details for the purposes of illustration, anyone of ordinary skill in the art will appreciate that many variations and alterations to the following details are within the scope of the present disclosure. Accordingly, example embodiments of the present disclosure described below are set forth without any loss of generality to, and without imposing limitations upon, the claimed invention.

In the following Detailed Description, reference is made to the accompanying drawings, which form a part hereof, and in which are shown by way of illustration specific embodiments in which the invention may be practiced. In this regard, directional terminology, such as “top,” “bottom,” “front,” “back,” “leading,” “trailing,” etc., is used with reference to the orientation of the figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

The disclosure herein refers to a semiconductor material, such as silicon, doped with ions of a first conductivity type or a second conductivity type. The ions of the first conductivity type may be opposite ions of the second conductivity type. For example, and without limitation, in some implementations, ions of the first conductivity type may be n-type, which contribute negative charge carriers, e.g., electrons, when doped into silicon. In such implementations, ions of the first conductivity type may include phosphorus, antimony, bismuth, lithium, and arsenic. In such implementations, ions of the second conductivity may be p-type, which create holes for charge carriers when doped into silicon and in this way are referred to as being the opposite of n-type. P-type type ions include boron, aluminum, gallium, and indium. While the above description referred to n-type as the first conductivity type and p-type as the second conductivity type the disclosure is not so limited, p-type may be the first conductivity type and n-type may be the second conductivity type. Furthermore, semiconductor materials other than silicon may be used in MOSFET devices in accordance with aspects of the present disclosure.

In the following Detailed Description, reference is made to the accompanying drawings, which form a part hereof, and which are shown by way of illustration of specific embodiments in which the invention may be practiced. For convenience, use of + or − after a designation of conductivity or net impurity carrier type (p or n) refers generally to a relative degree of concentration of a designated type of net impurity carriers within a semiconductor material. In general, terms, an n+ material has a higher n type net dopant (e.g., electron) concentration than an n material, and an n material has a higher carrier concentration than an n− material. Similarly, a p+ material has a higher p type net dopant (e.g., hole) concentration than a p material, and a p material has a higher concentration than a p− material. It is noted that what is relevant is the net concentration of the carriers, not necessarily dopant concentration. For example, a material may be heavily doped with n-type dopants but still have a relatively low net carrier concentration if the material is also sufficiently counter-doped with p-type dopants. As used herein, a concentration of dopants less than about 10¹⁵/cm³ may be regarded as “lightly doped” and a concentration of dopants greater than about 10¹⁷/cm³ may be regarded as “heavily doped”.

According to aspects of the present disclosure an improved DrMOS device may be created through the use of wafer level or panel level packaging with distributed contact placement in transistor devices providing a more uniform transistor device switching and reduced device area. Additionally, the use of distributed gate drive in a wafer level or panel level package may also improve the DrMOS device, reducing parasitic inductance, reducing device area, and improving robustness by splitting points of failure between multiple drivers. Finally, the use of both distributed contact placement and the distributed gate drive in a wafer level or panel level package may provide an enhanced DrMOS device with all of the previously mentioned benefits.

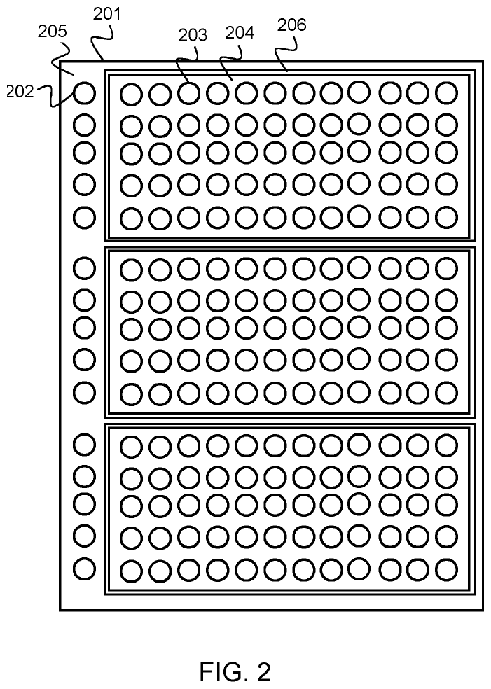

FIG. 2 is a top-down view of the redistribution layer (RDL) of a transistor device according to aspects of the present disclosure. As shown the transistor device 201 includes a gate RDL or gate top metal 205. The transistor device includes a source RDL or source top metal 204. Separation regions 206 insulate the source RDL or top metal from a gate RDL or top metal 205.

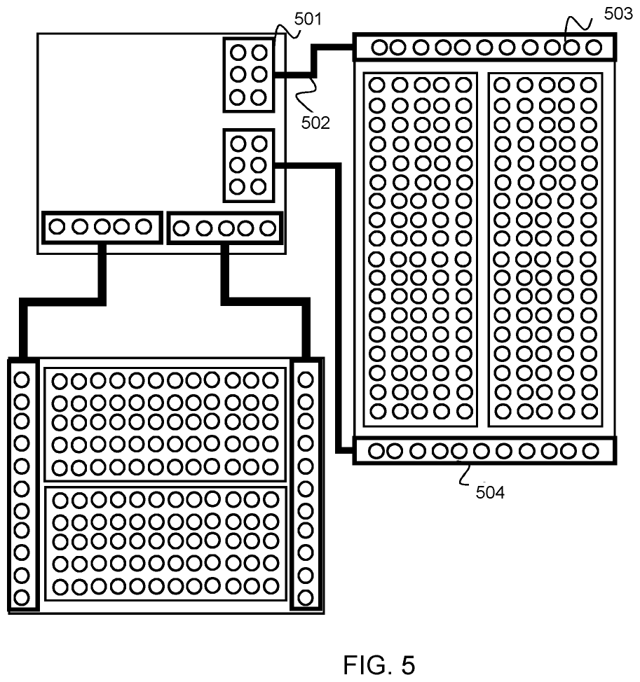

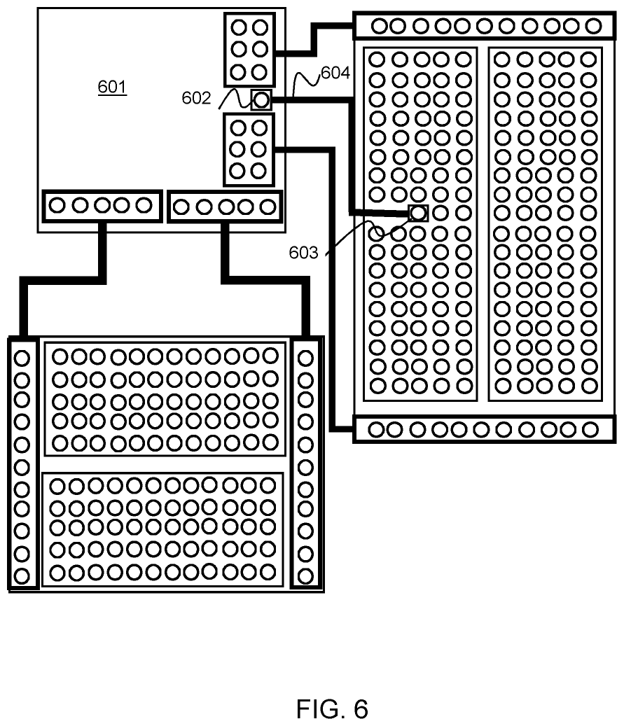

The gate RDL or top metal 205 as shown includes plated gate vias 202 through a gate insulating layer to the gate electrode. The gate electrode material may be distributed through the substrate composition to create a gate contact region along a top edge of the substrate composition. It should be noted that implementations are not limited to a gate contact region along a single top edge and the gate contact region may in one or more horizontal lines on top of the substrate composition in any area or run along two top edges as shown in FIGS. 5 and 6. Two or more vias through the gate insulating material expose portions of the gate electrode material in the gate contact region and conductive material of the plated gate vias 202 makes conductive contact with a portion of the gate electrode material on the edge of the transistor device. The two or more vias may be proportionally distributed over the gate contact region. There may be a sufficient number of vias of a suitable size to proportionally distribute voltage through the gate electrode. In some implementations the plated gate vias 202 may be filled with the conductive material of the gate RDL or gate metal layer. The gate RDL or gate metal layer may be made from, for example and without limitation, copper, aluminum, iron, tungsten, lead, or any alloy thereof.

Here when discussing the RDLs, reference to a source RDL, gate RDL, or drain RDL may be made, these refer to the RDL material in the RDL conductively coupled to the preceding element. For example, the gate RDL is the RDL material conductively coupled to the gate electrode through vias in a gate insulating layer. Similarly, a source RDL is the RDL material conductively coupled to the source regions and body regions through vias in a source insulating layer and a drain RDL material conductively coupled to the drain region through vias in a drain insulating layer. It should be understood that the source RDL and gate RDL may be different traces be on the same RDL layer or traces on different layers.

The source RDL or top metal 204 as depicted includes plated source vias 203 through a source insulating layer to a source contact. The source insulating layer and the gate insulating layer may be formed from the same material and formed at the same time. Thus, in some implementations the gate insulating layer and source insulating layer may be the same layer over the device substrate composition. The source and gate insulating layers may be made of an oxide, such as silicon dioxide, or another material, such as silicon nitride, which may be formed on top of gate electrode material, e.g., polysilicon or silicide. Two or more vias through the source insulating material expose the source region in the substrate composition and conductive material of the plated source vias 203 makes conductive contact with a portion of the source region. The two or more plated source vias may be proportionally distributed over the source RDL or Source metal. There may be a sufficient number of vias to proportionally distribute voltage through the gate region. Additionally, the plated source vias 203 may make conductive contact with a body region of the substrate composition forming the so called anti-parallel diode of a MOSFET device. In some implementations the plated source vias 203 may be filled with the conductive material of the source RDL or source metal layer. The source RDL or source metal layer may be made from for example and without limitation, copper, aluminum, iron, tungsten, lead, or any alloy thereof.

The distributed vias may improve device switching by more evenly distributing the contacts with the gate electrodes than implementations utilizing a single gate pad.

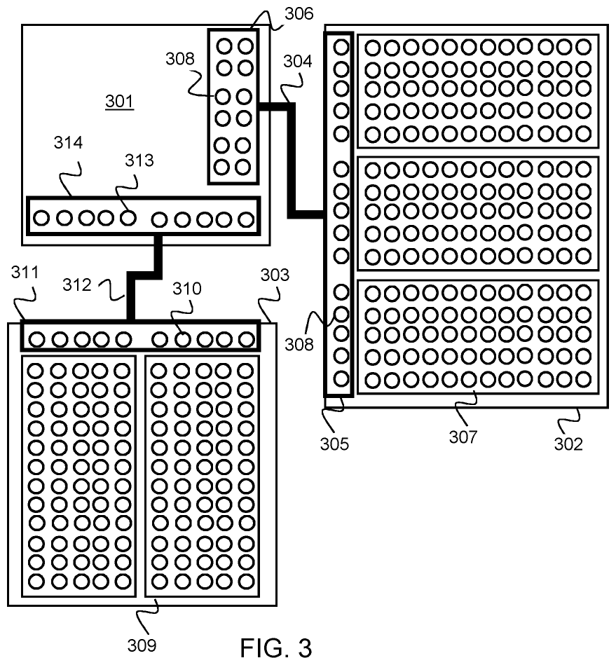

FIG. 3 is a top-down view of the RDL of a DRMOS device having a distributed gate drive with a single gate bus for the gates of each MOSFET according to aspects of the present disclosure. As shown the first FET device 302 and the second FET device 303 are each connected to the gate driver output nodes of the gate controller 301 via a single bus for each FET device. The gate controller 301 may be for example and without limitation a gate controller integrated circuit. The gate controller 301 may include gate drivers that are proportionally distributed between gate electrodes. In the example shown there are three gate drivers corresponding to the three gate contacts on the first FET device 302 plated vias 308 connect the gate drivers to an RDL 306 on the gate controller 301. The RDL 306 conductively couples each of the distributed drivers through the vias 308. A single Bus 304 in the RDL of the device connects the distributed drivers to the first gates of FET 302 through gate RDL 305. First FET device gate plated vias 308 connect the first FET device RDL 305 to the three gate electrodes of the first FET device 302. The first FET source RDL or source metal layer 307 also includes two or more plated vias which make contact with the source region of the FET device 302. As shown, there is a plurality of plated vias in the first FET device RDL or source metal. The distributed drivers improve the failure resistance of this device as it may continue to operate even if one driver fails.

Similarly, the second FET device 303 includes two sets of gate vias through a gate insulating layer that expose the gate electrode of the FET device. Conductive plating of the plated vias 310 connects the Gate RDL 311 to the gate electrodes. A second bus 312 formed from the RDL connects the gate electrodes to gate controller 301. Second plated vias 313 in the gate second gate RDL 314 connect the gate drivers to the second gate RDL 314 and the second bus 312. As shown, the second FET device Source RDL 309 includes a two or more plated vias which make conductive contact with the gate region of the FET device. Here, the first FET device may be a low side FET and the second FET may be a high side FET, but aspects of the present disclosure are not so limited, in some implementations the first FET device may be a high side FET and the second FET device may be a low side FET. By way of example, the high side FET and low side FET may be part of a voltage regulator. Furthermore, in some implementations, the illustrated configuration may be extended to multi-phase where one controller can be connected to multiple low side and high side devices. Additionally, while the implementations shown have two or three gate drivers' aspects of the present disclosure are not so limited and there may be any number of gate drivers sufficient to control the FET devices.

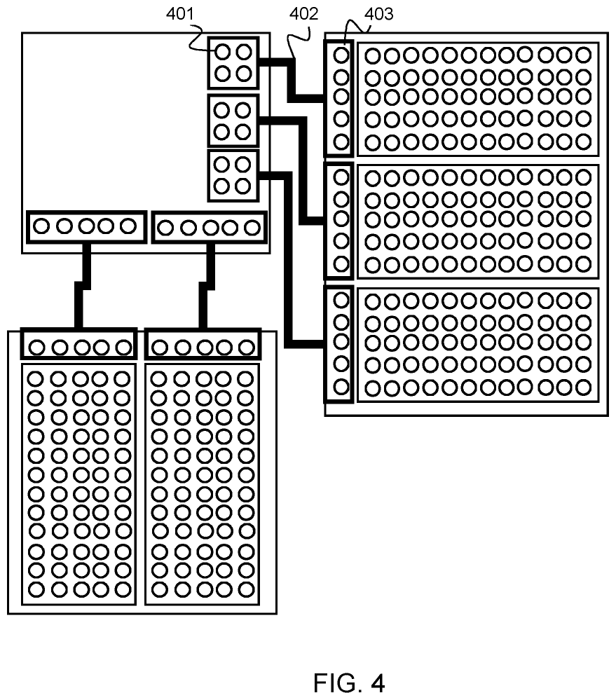

FIG. 4 is a top-down view of the RDL of a DRMOS device having a distributed gate drive with multiple proportionally distributed gate busses for the gates of each MOSFET according to aspects of the present disclosure. As shown, the three buses 402 are made from the RDL material. The three buses may be traces formed from the RDL layer. In alternative implementations the three traces may be wires made from a conductive material. The three buses are proportionally distributed between the three gate drivers of the gate controller. Plated vias 401 made through a gate controller insulating layer conductively couple the RDL material with the output nodes of each of the gate drivers for the first FET. In the implementation shown each output node of the gate drivers is conductively coupled to the RDL material through four plated vias 401. The three buses proportionally distribute connections to the three sets of gate electrode vias 403 in the RDL. Here the gate electrodes are connected by three sets of five plated vias 403 for the first FET Device. Similarly, the gate drivers for the second FET device are proportionally distributed with two busses made from the RDL material and connected between the gate electrode two sets of five gate vias through the gate insulating layer and two sets of five plated gate driver vias through a gate controller insulating layer.

FIG. 5 is a top-down view of the RDL of a DRMOS device having a distributed gate drive with multiple proportionally distributed gate busses for the gate electrode contact regions located on two top sides of each FET device according to aspects of the present disclosure. As shown gate contact regions are located on the first top edge 503 and a second top edge 504. Plated vias in the RDL material make conductive contact with the gate electrodes on the first top edge 503 and second top edge 504. Two buses 502 made from the RDL material conductively couple the gate electrodes with the gate driver output nodes through plated vias made from the RDL material 501. The two buses 502 proportionally distribute connections to the two gate contact regions and two gate drivers which are each conductively coupled to the buses through six plated vias.

FIG. 6 is a top-down view of the RDL of a DRMOS device having a distributed gate drive with multiple proportionally distributed gate busses for the gate electrode contact regions located on two top sides of each FET device including a sense FET according to aspects of the present disclosure. Having edge-located contact regions for the gate electrodes allows new possibilities for locations of a sense FET. Typically sense FETs are located on an edge of the device for ease of connection. This provides less than ideal sensing because the sense FET is separated from the rest of the FET device area. As shown, the sense FET source region 603 is located in the middle of the source regions allowing more accurate sensing of the operation. The two edge contact regions, keep RDL material busses out of the way. The sense FET source region is connected to a sense FET RDL material through a conductive via. A special sense gate bus 604 made from the RDL material connects the sense FET source region to a sense FET node of the gate controller IC 601 through a conductive via 602. While the implementation shown includes two edge contact regions for the gate electrode material aspects of the present disclosure are not so limited, the sense FET located in the middle of source regions may be implemented with a single edge contact region or three or more edge contact regions.

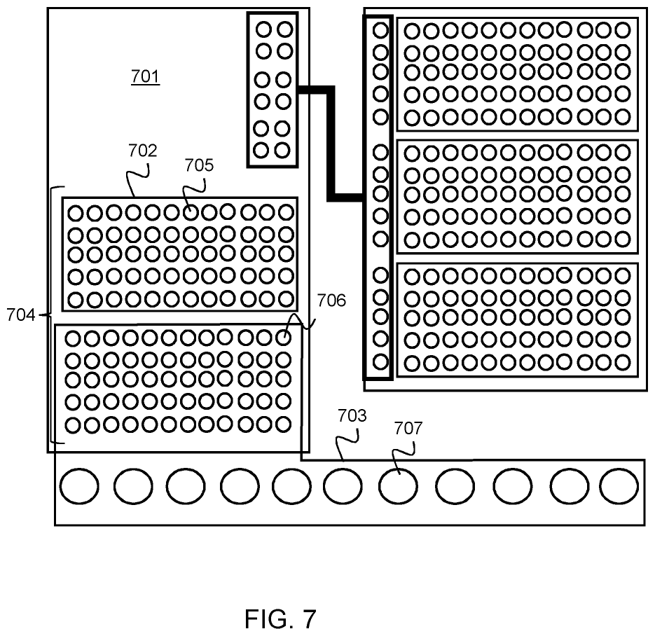

FIG. 7 is a top-down view of the RDL of a DRMOS device having a FET device integrated with the gate control and a distributed gate drive with multiple proportionally distributed gate busses for the gate electrode contact regions located on a top edge of the separate FET device according to aspects of the present disclosure. As shown the gate controller 701 includes an integrated FET 704. The integrated FET may be for example and without limitation the high side FET. An integrated FET drain RDL 702 may include an RDL having plated vias 705 in conductive contact with the drain region of the integrated FET 704. The plated vias 705 may be proportionally distributed over the drain region of the integrated FET. The integrated FET drain RDL 702 may run to a drain connection node for the DRMOS device. An integrated FET source RDL 703 may make conductive contact with the source regions of the integrated FET 704 through plated vias 706. The integrated FET source RDL 703 may also include plated vias 707 through a molding material layer to a source connection node for the DRMOS device. Additionally, the DRMOS device may include a separate FET device and distributed drivers similar to those seen in previous implementations.

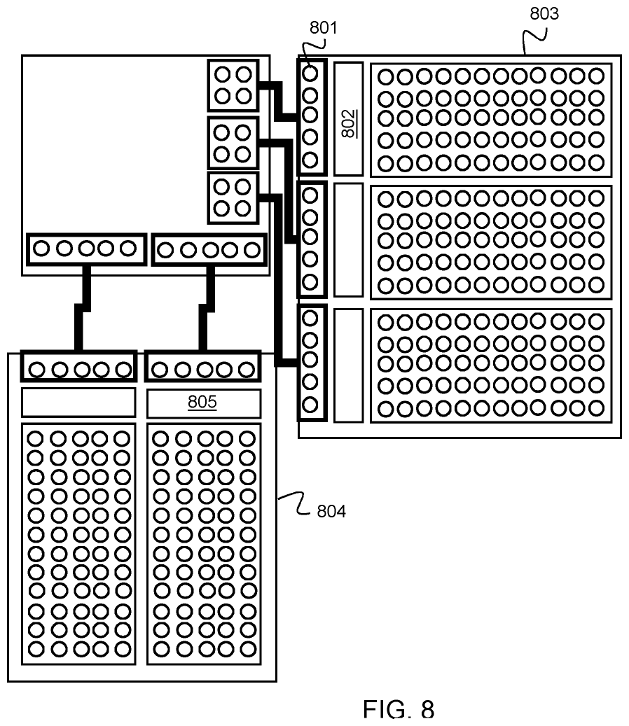

FIG. 8 is a top-down view of the RDL of a DRMOS device having integrated trench capacitors in the semiconductor substrate composition according to aspects of the present disclosure. As shown here the first FET device 803 includes on-chip trench capacitors 802 formed in the substrate composition of the first FET device. In some alternative implementations the on-chip capacitors may be planar capacitors. The plated vias 801 may be in conductive contact with the gate electrode material in the gate contact region at a top edge of the substrate composition. The trench capacitors may also be in conductive contact with the gate electrode of the gate of the FET device. The second FET device 804 may also include trench capacitors 805 similarly coupled to the gate electrode material. The gate electrode material in the contact region is in conductive contact with the trench capacitors. Here, each distributed gate driver is coupled to a separate trench capacitor through the gate RDL. Aspects of the present disclosure are not so limited and may include for example and without limitation a single trench capacitor structure in conductive contact with each of the gate drivers or multiple trench capacitor structures in conductive contact with a single gate driver.

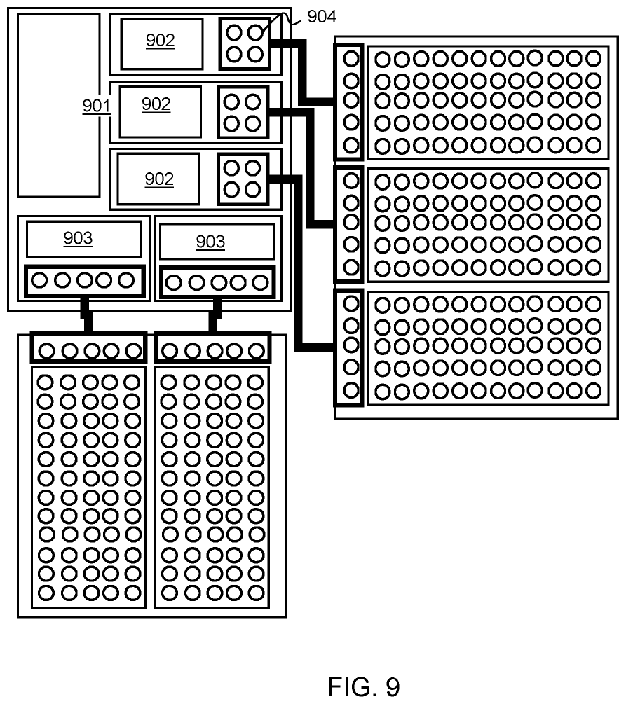

FIG. 9 is a top-down view of the RDL of a DRMOS device illustrating the distributed gate drivers according to aspects of the present disclosure. Here, the gate controller 901 includes gate drivers 902 for the first FET device and the gate drivers 903 for the second FET which are visible. It further can be seen that each of the gate drivers 902 for the first FET device and the gate drivers 903 for the second FET device are coupled to their respective FET devices through plated vias 904. The distributed gate drivers provide redundancy should a driver fail and in implementations that include multiple RDL traces connecting the gate electrode, better distribution of energy to the gate electrodes.

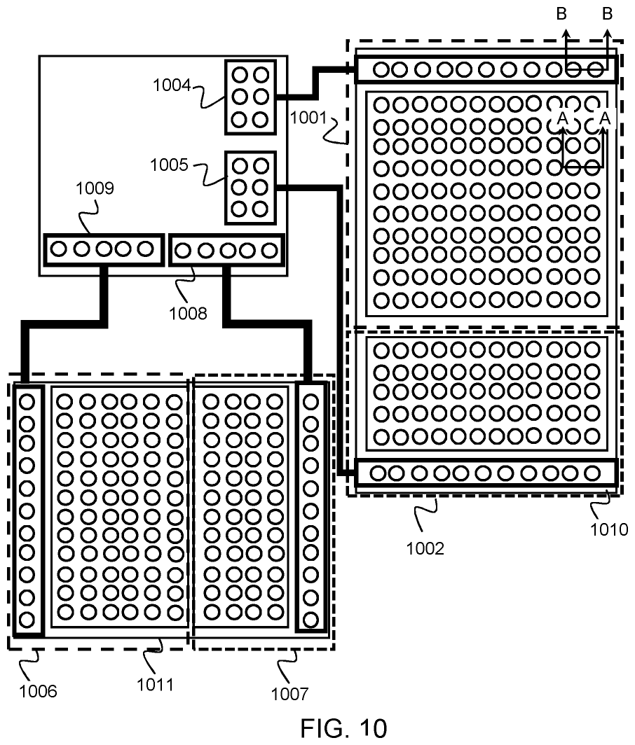

FIG. 10 is a top-down view of the RDL of a DRMOS device including split FET devices according to aspects of the present disclosure. In the implementation shown the first FET device 1010 includes two separate gate structures of uneven size. Shown here the first gate structure 1001 of the First FET device is the larger sized gate which is used in normal device operation. Here the size of the gate refers to the amount of device area taken up by the gate electrode. The second gate structure 1002 of the first FET device is a smaller sized gate that may be used during light load conditions. In some implementations, the distributed drivers for the first FET may be proportionally distributed between the first gate structure 1001 and the second gate structure 1002. Specifically, a larger FET may have larger distributed drivers than a smaller FET. Shown here a first gate driver is connected to the first gate structure through plated vias to a first gate structure RDL 1004. The second gate driver is connected to the second gate structure through plated vias to a second gate structure RDL 1005.

Similarly, the second FET device 1011 includes two separate gate structures of uneven size. The first gate structure 1006 of the second FET device is the larger sized gate which is used in normal device operation. The second gate structure 1007 of the first FET device is a smaller sized gate that may be used during light load conditions. The distributed drivers for the first FET may also be evenly split between the first gate structure 1006 and the second gate structure 1007. Shown here a first gate driver is connected to the first gate structure through plated vias to a first gate structure RDL 1009. The second gate driver is connected to the second gate structure through plated vias to a second gate structure RDL 1008. As with the first FET device 1010, the distributed drivers for the second FET device 1011 may be proportionally distributed between the first gate structure 1006 and the second gate structure 1007. The larger of the two FETs may have larger distributed drivers than the smaller of the two.

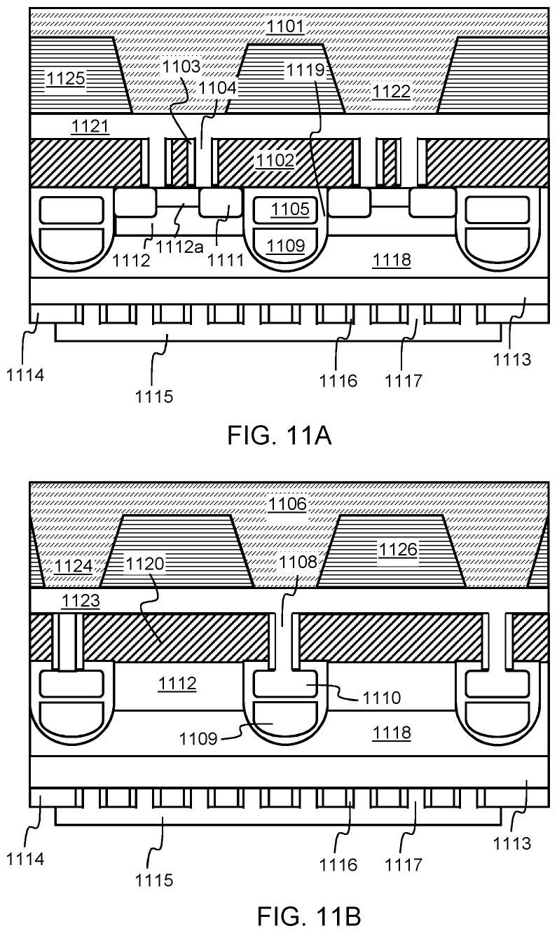

FIG. 11A and FIG. 11B are cutaway side views of a shielded gate trench (SGT) MOSFET device in an implementation of the DRMOS according to aspects of the present disclosure. FIG. 11A depicts a cross-section of the device region under a source region RDL 1101 and FIG. 11B depicts a cross-section of the gate contact region under a gate RDL 1106. As shown the device includes a substrate composition includes having a substrate layer 1113 heavily doped with ions of the first conductivity type, a drift region 1118 formed on top of the substrate layer lightly doped with ions of the first conductivity type, a body region 1112 formed in the drift region and doped with ions of the second conductivity type. Source regions 1111 are formed in an upper portion of the body region and heavily doped with ions of the first conductivity type. Here the substrate composition may be a semiconductor material, for example and without limitation, gallium nitride, silicon, or silicon carbide.

The substrate composition includes trenches with a trench insulating layer 1119 lining a surface of each of the trenches. In the implementation shown a shield electrode 1109 is located over a bottom surface of the trenches on the trench insulating layer 1119. The trench insulating layer 1119 extends over the shield electrode 1109. Gate electrode 1105 is located over the shield electrode 1109 on the trench insulating layer 1119. The trench insulating layer 1119 also covers the gate electrode. It should be noted that each source region 1111 is further located near a side of a trench. Additionally, while an SGT structure is shown aspects of the present disclosure are not so limited and a trench gate structure may be made by simply excluding the shield electrode. The gate electrodes 1105 are connected to a gate contact region by gate runners 1110, which make electrical contact to a gate RDL 1106 through plated vias 1124 in a molding material layer 1126 to a gate metal layer 1123 and electrically conductive vias 1108 in the gate contact region insulating layer 1120, as shown in FIG. 11B. The shield electrodes 1109 may be conductively coupled to the source region RDL 1101 (not shown). The RDL vias may be formed by laser ablation and may be 20 micrometers in diameter or less.

As shown in FIG. 11B, the gate RDL 1106 extends along a top edge of the substrate composition. The gate RDL 1106 may be formed from the same material as the source region RDL 1101, e.g., through conventional metal deposition and patterning techniques.

A source insulating layer 1102 is located on top of the substrate composition under a source region top metal 1121 and over the source regions 1111 and body regions 1112. Vias 1103 are formed in the source insulating layer exposing a portion of the source region 1111 and a portion of the body region 1112. In some implementations, there may be a doped region 1112a of the second conductivity type between the two source regions 1111 of the first conductivity type. The doped region 1112a is more heavily doped than the body regions 1112. For example, if the body regions or P-type and the source regions are N-type, the doped region 1112a may be doped P+. Alternatively, a shallow trench P+ contact plug may be formed into body region, shorting the N+ and P+/Pbody on the vertical sides of the shallow trench contact plug.

A conductive material may plate the vias 1104, as shown here and the conductive material may fill each via. Here, for example and without limitation the top metal may be aluminum, copper, tungsten, nickel, iron, or any alloy thereof. The conductive via makes conductive contact with both the source region 1111 and the body region 1112 forming the anti-parallel diode. The source top metal 1121 is in conductive contact with the source RDL layer 1101 through plated RDL vias 1122. RDL Vias in the molding material layer 1125 expose the source top metal 1121. The RDL material may plate the sides of the vias and in some implementations, e.g., as shown here, may fill the entire RDL via 1122. The conductive RDL vias 1122 may be proportionally distributed over source region top metal and conductively coupled with the source regions and body regions of the substrate composition.

As shown in FIG. 11B, a gate contact region insulating layer 1120 covers the top of the substrate composition over the gate contact region. Vias 1108 through the gate contact region insulating layer 1120 and trench insulating layer in the gate contact region exposes the gate electrode material that forms the gate runners 1110. Gate RDL 1106 is located on top of the gate contact region insulating layer 1120. The gate RDL 1106 may plate the gate RDL vias 1124and fill each via. The conductive gate RDL vias 1124 may make conductive contact with the gate metal layer 1123. The gate metal layer 1123 may plate gate contact vias 1108 and fill each via. The conductive gate vias make conductive contact with the gate runners 1110, which are formed in insulated trenches in a similar fashion to the gate electrodes 1105. Portions of the shield electrodes 1109 may also be formed in the trenches along with the gate runners 1110. The RDL vias may be proportionally distributed over the gate contact region 1110. Here the gate electrode material and a shield electrode material may be a conductive material such as poly crystalline silicon.

In the implementation shown, the substrate layer 1118 acts as a backside drain contact region. A drain insulating layer 1114 is formed under the bottom of the substrate composition. Vias 1116 formed through the drain insulating layer 1114 expose the substrate 1118. A drain RDL or metal layer 1115 is located underneath the drain insulating layer 1114. The drain RDL plates the vias 1117 as shown here the drain RDL plates and fills the entire via. Here the drain RDL, source RDL, and gate RDL may be made from a conductive material for example and without limitation copper, aluminum, nickel, tungsten, gold, silver, or any alloy thereof.

It is noted that for implementations that utilize trench capacitors, such as trench capacitors 805 of FIG. 8, the trench capacitors may formed utilizing both the gate electrode 1105 and shield electrode 1109 in any combination to the source terminal or to the drain terminal. For example, a trench capacitor can be formed between the top gate electrode 1105 as one terminal of the capacitor to source metal as the other terminal of the capacitor (with the shield electrode 1109 tied to a source terminal).

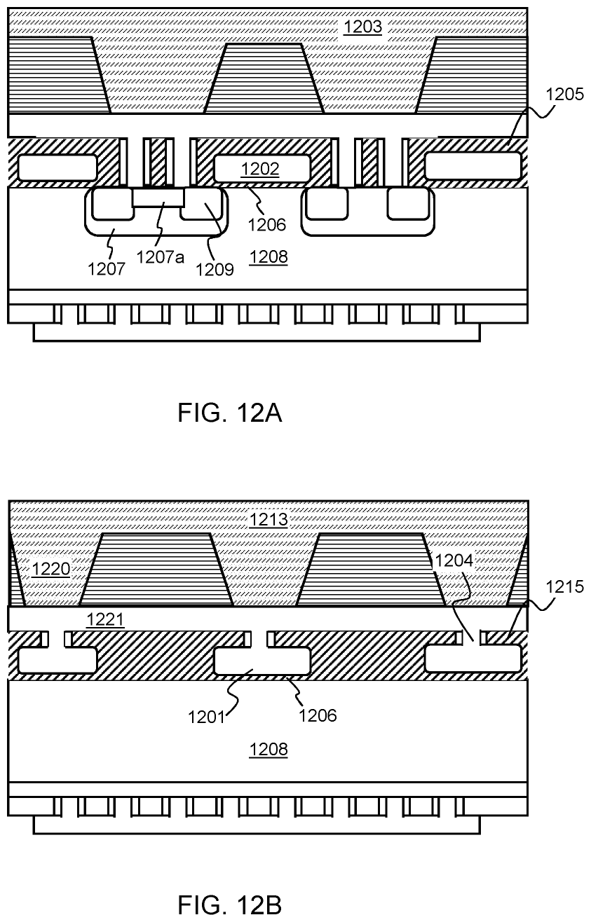

FIG. 12A and FIG. 12B are cutaway side views of a planar gate MOSFET device in an implementation of the DRMOS according to aspects of the present disclosure. FIG. 12A depicts a cross-section of the device region under a source region RDL 1203 and FIG. 12B depicts a cross-section of the gate contact region under a gate RDL 1213. In this implementation body regions 1207 heavily doped with ions of the second conductivity type are formed in body regions 1208 under the source region RDL 1203. Source regions 1209 heavily doped with ions of first conductivity type are formed in the body region. In some implementations, there may be a doped region 1207a of the second conductivity type between the two source regions 1209. The doped region 1207a is more heavily doped than the body region 1207. Alternatively, a shallow trench contact plug of the second conductivity type may be formed into body region, shorting the source and body regions on the vertical sides of the shallow trench contact plug.

Planar gate electrodes 1202 are located over the substrate composition on a planar gate insulating layer 1206. In some implementations, the planar gate insulating layer may wrap around the planar gate electrodes 1202. In an alternative implementation a source insulating layer 1215 may insulate the top and sides of the planar gate electrodes. A portion of the planar gate electrode overlaps the source region and body region.

As shown in FIG. 12B, planar gate runners 1201 make electrical contact between the gate RDL 1213 and the gate electrodes 1202. The gate RDL may be located on the top edge of the substrate composition, e.g., as shown in FIG. 10. A gate electrode contact region insulating layer 1215 is located over top of the substrate composition in the planar gate electrode contact region. The gate RDL 1213 extends over the gate electrode contact region insulating layer 1215. Gate vias 1204 through the gate electrode contact region insulating layer 1215 expose the gate electrode material that forms the planar gate runners 1201. The gate RDL 1213 may plate gate RDL vias 1204 and may fill the entire via making contact with a gate top metal layer 1221. The gate metal layer 1221 may plate the gate vias 1204 and may file the entire via making contact with the gate electrode material. The RDL vias 1220 may be proportionally distributed over the gate electrode contact region.

Improved DrMOS devices of the types described herein may be created with distributed contact placement in transistor devices providing a more uniform transistor device switching and reduced device area. Additionally, the use of distributed gate drive in a wafer level or panel level package may also reduce parasitic inductance, reduce device area, and improve robustness by splitting points of failure between multiple drivers. Finally, the use of both distributed contact placement and the distributed gate drive provides an enhanced DrMOS device with all of the previously mentioned benefits.

While the above is a complete description of the preferred embodiment of the present invention, it is possible to use various alternatives, modifications, and equivalents. Therefore, the scope of the present invention should be determined not with reference to the above description but should, instead, be determined with reference to the appended claims, along with their full scope of equivalents. Any feature described herein, whether preferred or not, may be combined with any other feature described herein, whether preferred or not. In the claims that follow, the indefinite article “A.” or “An” refers to a quantity of one or more of the item following the article, except where expressly stated otherwise. The appended claims are not to be interpreted as including means-plus-function limitations, unless such a limitation is explicitly recited in a given claim using the phrase “means for.”

What is claimed is:

1. A transistor device comprising;
a semiconductor substrate composition;
a first gate electrode material disposed over a portion of a surface of the semiconductor substrate composition wherein the first gate electrode material includes a first gate electrode contact region near at least one edge of the substrate composition;
a gate insulating material over the first gate electrode material including two or more first gate vias through the gate insulating material in the first gate electrode contact region wherein the two or more first gate vias expose the first gate electrode material.

2. The transistor device of claim 1 further comprising a source region formed in the substrate composition; and
a source region insulating material disposed over the source region including two or more source vias through the source insulating material, wherein the two or more source vias expose a top of the substrate composition in the source region.

3. The transistor device of claim 1 further comprising a conductive first gate redistribution material conductively coupled to a first gate metal layer, wherein the first gate metal layer at least lines the two or more first gate vias and conductively couples each of the first gate vias to each other.

4. The transistor device of claim 3 wherein the first gate redistribution material is connected to an output node of a gate controller.

5. The transistor device of claim 1 wherein two or more first gate redistribution layer vias are proportionally distributed over the first gate electrode contact region.

6. The transistor device of claim 2 further comprising a conductive source redistribution material conductively coupled to a source region top metal at least lining the two or more source vias and conductively coupling each of the source vias.

7. The transistor device of claim 6 wherein the conductive source redistribution material is connected to a source contact node for the transistor device.

8. The transistor device of claim 2 wherein two or more source redistribution layer vias are proportionally distributed over the source region.

9. The transistor device of claim 1 further comprising a drain region formed in the backside of the substrate composition and a drain insulating material over the backside drain region including two or more vias through the drain insulating material for connection to drain metal or a drain redistribution layer.

10. The transistor device of claim 1 further comprising a second gate electrode over the surface of the substrate composition and wherein the gate insulating material further includes two or more second gate vias exposing the second gate electrode for connection.

11. The transistor device of claim 2 further comprising a sense FET source region formed in the substrate composition and wherein the source region insulating material includes at least one via through the source region insulating material over the Sense FET source region exposing the sense FET gate source region for connection.

12. The transistor device of claim 11 further comprising a sense FET source redistribution material conductively couples the sense FET source region to a Sense FET node of a gate controller.

13. The transistor device of claim 11 wherein the sense FET gate is located in a center of a source region.

14. The transistor device of claim 1 wherein vias from a redistribution layer to a gate metal layer in conductive contact with the first gate electrode material are 20 micrometers in diameter or less.

15. The transistor device of claim 1 further comprising an on chip capacitor formed in the substrate composition wherein the on chip capacitor connects the gate electrode to the first gate electrode contact region.

16. The transistor device of claim 1 wherein the first gate electrode material is formed in a trench of the substrate composition.

17. The transistor device of claim 16 wherein at least a portion of the first gate electrode material is formed over a conductive shield electrode in the trench of the substrate composition.

18. The transistor device of claim 1 wherein the first gate electrode material is part of a planar gate structure on the surface of the substrate composition.

19. A distributed drive package comprising:
a first transistor device having two or more first gate vias on a first top edge portion of the first transistor device electrically connecting a first gate electrode material;
a gate controller integrated circuit including a first gate driver output node; and
a first gate conductive redistribution material conductively coupling the first gate electrode material of the first transistor device to the first gate driver output node through the two or more first gate vias.

20. The distributed drive package of claim 19 further comprising a second transistor device having two or more second gate vias along a top edge of the second transistor device exposing a second gate electrode material and a second gate conductive redistribution material conductively coupling the second gate electrode material to a second gate output node of the gate controller integrated circuit.

21. The distributed drive package of claim 20 wherein the first transistor device is a low side field effect transistor and the second transistor is a high side field effect transistor for a voltage regulator.

22. The distributed drive package of claim 19 wherein the first gate redistribution material includes two or more connections between the first gate driver output node and a first gate metal layer to the first gate electrode material through two or more Redistribution layer vias.

23. The distributed drive package of claim 22 wherein the two or more connections are proportionally distributed between the two or more redistribution layer vias.

24. The distributed drive package of claim 22 wherein the two or more connections are each formed between two or more first gate driver output nodes on the first gate driver integrated circuit and the first gate electrode material.

25. The distributed drive package of claim 19 wherein the first gate conductive redistribution material includes a metal wire connected to the first gate driver output node and conductively coupled to the first gate electrode material.

26. The distributed drive package of claim 19 wherein the first gate conductive redistribution material includes one or more conductive traces conductively coupled to the first gate driver output node and conductively coupled to the first gate electrode material.

27. The distributed drive package of claim 19 wherein the first transistor device includes two or more additional first gate vias on a second top edge portion of the first transistor device and wherein the first gate conductive redistribution material also conductively couples the first gate electrode material of the first transistor device to the first gate driver output node of the gate controller integrated circuit through the two or more additional first gate vias on the second top edge portion of the substrate composition.

28. The distributed drive package of claim 19 wherein the gate controller integrated circuit includes a second gate driver output node and wherein the first transistor device includes two or more second gate vias on a second top edge portion of the first transistor device and wherein a second gate conductive redistribution layer conductively couples a second gate electrode material of the first transistor device to the second gate driver output node through the two or more second gate vias on the second top edge portion of the substrate composition.

29. The distributed drive package of claim 27 wherein the two or more second gate vias are proportionally distributed over a second gate electrode contact region.

30. The distributed drive package of claim 19 wherein the first transistor device includes at least one on-chip capacitor.

31. The distributed drive package of claim 19 wherein the gate controller integrated circuit is a monolithic integrated circuit including a second transistor device.

32. The distributed drive package of claim 19 wherein the first transistor device includes a sense FET and a sense FET redistribution material between the sense FET and a Sense FET node on the gate controller integrated circuit.
